(19) United States
(12) Patent Application Publication
(10) Pub. No.: US 2015/0235689 A1
(43) Pub. Date: Aug. 20, 2015

(54) SEMICONDUCTOR MEMORY DEVICE AND CONTROL METHOD THEREOF

(71) Applicant: FUJITSU SEMICONDUCTOR LIMITED, Yokohama-shi (JP)

(72) Inventor: Shoichiro KAWASHIMA, Yokohama (JP)

(21) Appl. No.: 14/601,975

(22) Filed: Jan. 21, 2015

(30) Foreign Application Priority Data
Feb. 14, 2014 (JP) 2014-026608

(51) Int. Cl. G11C 11/22; G11C 5/14; G11C 7/06

(52) U.S. Cl. CPC G11C 11/221; G11C 7/06; G11C 5/147

(57) ABSTRACT

A semiconductor memory device includes: a memory cell array including a memory cell, which includes a ferroelectric capacitor and an access transistor which is a first conductive type transistor formed in a second conductive type well and includes a source or a drain connected to one electrode of the ferroelectric capacitor; and a control circuit which controls a potential applied to the second conductive type well. The control circuit applies a fixed potential to another electrode of the ferroelectric capacitor and applies a second potential being a forward voltage with respect to a junction between the first conductive type source and drain and the second conductive type well when erasing data in the memory cell, and applies a third potential not being the forward voltage with respect to the junction between the first conductive type source and drain and the second conductive type well in a normal operation.

### CROSS-REFERENCE TO RELATED APPLICATION

This application is based upon and claims the benefit of priority of the prior Japanese Patent Application No. 2014-026608, filed on Feb. 14, 2014, the entire contents of which are incorporated herein by reference.

### FIELD

The embodiments discussed herein are directed to a semiconductor memory device and a control method thereof.

### BACKGROUND

One of non-volatile memories each using a memory cell having a capacitor and a field effect transistor (FET) as a storage element is a ferroelectric random access memory (FeRAM). Each memory cell of the ferroelectric random access memory has a ferroelectric capacitor having one electrode connected to a plate line and another electrode connected to a bit line via a selection transistor. A gate of the selection transistor is connected to a word line to enable selective access to the ferroelectric capacitor.

As a high-speed erasing method for data in the non-volatile ferroelectric random access memory, there is proposed a method of collectively erasing data in a plurality of cells (refer to, for example, Patent Documents 1, 2). For example, there is a method of selecting multiple word lines to set the bit line and the plate line to certain potentials to reset polarization of ferroelectric capacitors in the plurality of selected memory cells in one direction so as to perform collective erasure. This can be realized by providing a function of selecting a plurality of word lines at the same time in a driver (driving circuit).

Patent Document 1: Japanese Laid-open Patent Publication No. 2000-48577

Patent Document 2: Japanese Laid-open Patent Publication No. 8-139286

Here, one ferroelectric capacitor used for the ferroelectric random access memory has a capacitance value of about 100 fF. Therefore, in the method of selecting multiple word lines to collectively erase stored data, the load on the bit line increases due to the multiple selection of the word lines, bringing about problems of requiring time to bring the bit line to the certain potential and causing the peak value of current to be very large. Further, addition of a circuit for selecting the plurality of words line at the same time brings about a problem of greatly increasing, for example, a circuit area of a decoder.

Besides, there is a conceivable method in which a sequencer for an erasing operation is provided to erase data by sequentially selecting words lines one by one in a state that the bit line and the plate line are kept at the certain potentials. Since a restore operation is not performed unlike the normal operation, data can be erased at a speed higher than normal. This method can suppress the peak value of current in the data erasure but requires time to sequentially erase the word lines, and is thus not suitable for erasing data, for example, in the process of voltage reduction by power off.

### SUMMARY

An aspect of a semiconductor memory device includes: a memory cell array including a memory cell, the memory cell including a capacitor and an access transistor, the access transistor being a first conductive type transistor formed in a second conductive type well and including a source and a drain one of which is connected to one electrode of the capacitor and another of which is connected to a bit line; and a control circuit which controls a potential applied to the second conductive type well. The control circuit applies a first potential to another electrode of the capacitor and applies a second potential to the second conductive type well when erasing data in the memory cell, and applies a third potential to the second conductive type well in a normal operation. The first potential is a fixed potential, the second potential is a forward voltage with respect to a junction between the first conductive type source and drain and the second conductive type well, the third potential is not the forward voltage with respect to the junction between the first conductive type source and drain and the second conductive type well.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a configuration example of a semiconductor memory device in an present embodiment invention;

FIG. 2A and FIG. 2B are views for explaining configuration examples of memory cells and a data erasing method in this embodiment;

FIG. 3A and FIG. 3B are views for explaining configuration examples of memory cells and a data erasing method in this embodiment;

FIG. 4 is a diagram illustrating a configuration example of a cell well potential control circuit in this embodiment;

FIG. 5 is a diagram illustrating an example of a semiconductor memory device in a first embodiment;

FIG. 6 is a diagram illustrating an example of a semiconductor memory device in a second embodiment;

FIG. 7 is a diagram illustrating a configuration example of a level detection circuit;

FIG. 8 is a diagram illustrating another example of the semiconductor memory device in the second embodiment;

FIG. 9 is a diagram illustrating an example of a semiconductor memory device in a third embodiment;

FIG. 10 is a diagram illustrating an example of a semiconductor memory device in a fourth embodiment;

FIG. 11 is a diagram illustrating an example of a semiconductor memory device in a fifth embodiment;

FIG. 12 is a diagram illustrating a configuration example of a level shifter circuit;

FIG. 13 is a diagram illustrating an example of a semiconductor memory device in a sixth embodiment;

FIG. 14 is a diagram illustrating an example of a semiconductor memory device in a seventh embodiment;

FIG. 15 is a diagram illustrating an example of a semiconductor memory device in an eighth embodiment;

FIG. 16 is a diagram illustrating an example of a semiconductor memory device in a ninth embodiment;

FIG. 17 is a diagram illustrating an example of a semiconductor memory device in a tenth embodiment;

FIG. 18 is a diagram illustrating an example of a semiconductor memory device in an eleventh embodiment;

FIG. 19 is a diagram illustrating an example of a semiconductor memory device in a twelfth embodiment;

FIG. 20 is a diagram illustrating an example of a semiconductor memory device in a thirteenth embodiment;

FIG. 21A and FIG. 212 are views illustrating arrangement examples of memory cells and their peripheral circuits in this embodiment; and

FIG. 22 is a chart illustrating an example of a hysteresis curve of a ferroelectric capacitor.

### DESCRIPTION OF EMBODIMENTS

Hereinafter, embodiments will be explained with reference to the drawings.

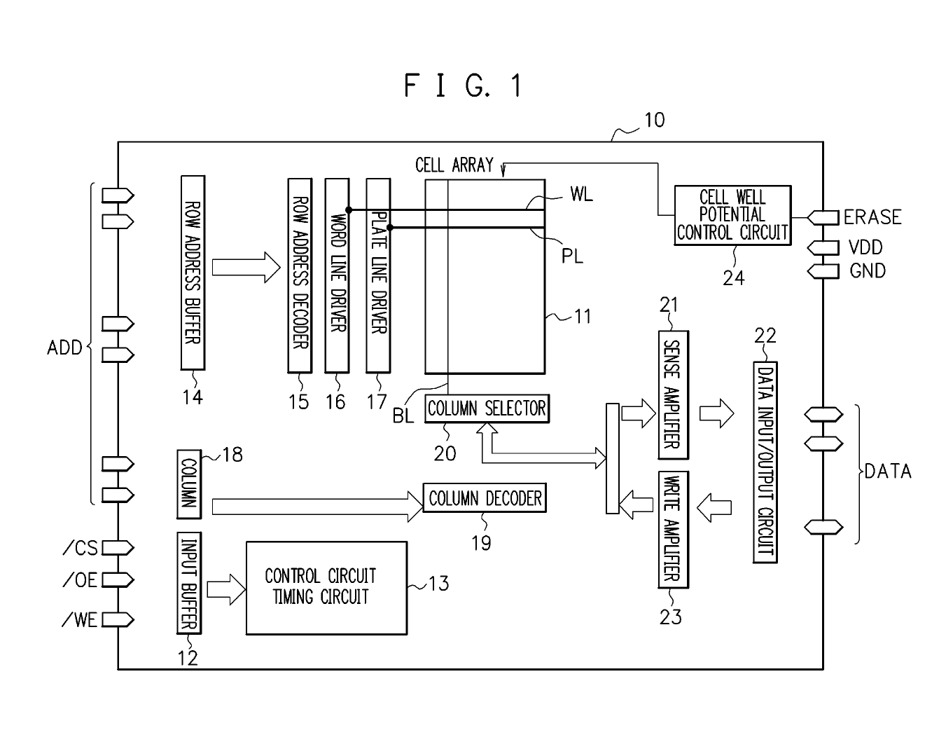

FIG. 1 is a diagram illustrating a configuration example of a semiconductor memory device in an present embodiment. A semiconductor memory device 10 in this embodiment includes a memory cell array 11, an input buffer 12, a control circuit and timing circuit 13, a row address buffer 14, a row address decoder 15, a word line driver (driving circuit) 16, a plate line driver (driving circuit) 17, a column buffer 18, a column decoder 19, a column selector 20, a sense amplifier 21, a data input/output circuit 22, a write amplifier 23, and a cell well potential control circuit 24.

The memory cell array 11 has a plurality of memory cells arrayed in a matrix form. A memory cell is arranged at an intersection part of a word line WL and a bit line BL. A plurality of memory cells arrayed on the same row are connected to one word line WL and one plate line PL. A plurality of memory cells arrayed on the same column are connected to one bit line BL.

Each of the memory cells is, for example, a non-volatile memory cell, and has a capacitor and an access transistor. The capacitor is, for example, a ferroelectric capacitor, and the access transistor is a field effect transistor (FET). The capacitor has one electrode connected to one of a source and a drain of the access transistor, and another electrode connected to the plate line PL. The other of the source and the drain of the access transistor is connected to the bit line BL, and a gate of the access transistor is connected to the word line WL.

Control signals such as a chip select signal /CS (/ indicating a negative logic, this also applying hereafter), an output enable signal /OE, a write enable signal /WE and so on which are inputted to the semiconductor memory device 10 are inputted into the control circuit and timing circuit 13 via the input buffer 12. The control circuit and timing circuit 13 controls the operation inside the semiconductor memory device 10 and its operation timing according to the inputted control signals.

A part (row part) of an address signal ADD inputted into the semiconductor memory device 10 is inputted to the row address decoder 15 via the row address buffer 14. The row address decoder 15 decodes the inputted address signal ADD. The word line driver 16 and the plate line driver 17 drive the word line WL and the plate line PL respectively, according to the decoded result by the row address decoder 15 and the control by the control circuit and timing circuit 13.

A part (column part) of the address signal ADD inputted into the semiconductor memory device 10 is inputted to the column decoder 19 via the column buffer 18. The column decoder 19 decodes the inputted address signal ADD. The column selector 20 selects a column according to the decoded result by the column decoder 19 and the control by the control circuit and timing circuit 13.

The sense amplifier 21 senses the potential of the bit line on the column selected by the column selector 20 in reading data from the memory cell array 11. An output of the sense amplifier 21 is outputted as data DATA via the data input/output circuit 22. The data DATA inputted into the semiconductor memory device 10 is written into the memory cells of the memory cell array 11 via the data input/output circuit 22 and the write amplifier 23.

The cell well potential control circuit 24 controls the potential of well of the memory cell array 11 according to the voltage inputted into a terminal ERASE of the semiconductor memory device 10. The cell well potential control circuit 24 controls the potential of the well to apply forward bias to a PN junction between the source and drain of the access transistor and the well where the source and drain of the access transistor are formed, according to the input voltage to the terminal ERASE in a data erase operation in the memory cell array 11.

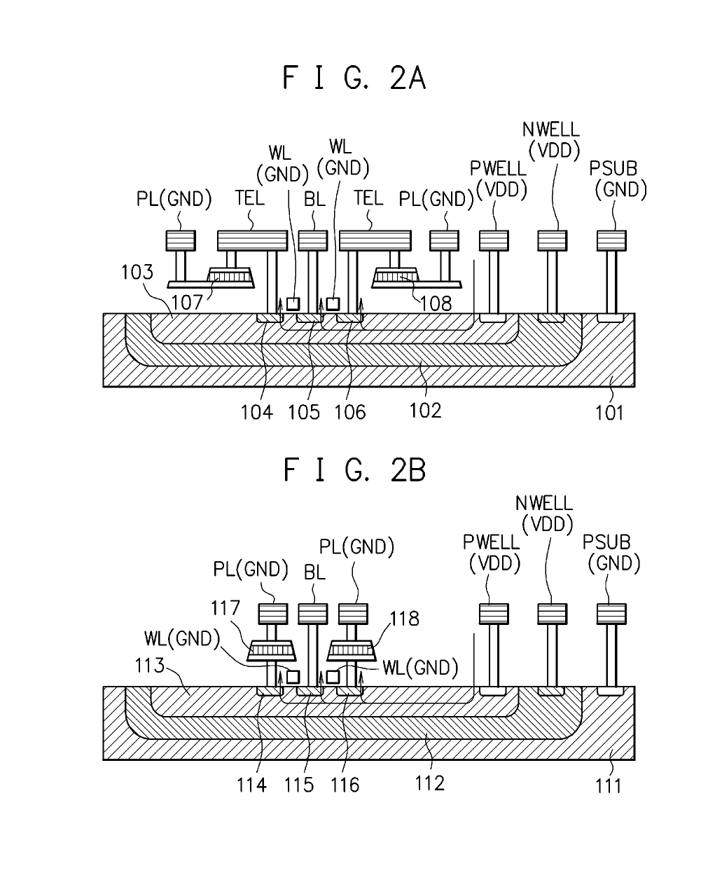

FIG. 2A and FIG. 2B are views illustrating configuration examples of memory cells and potentials applied during erasure in this embodiment. FIG. 2A and FIG. 2B illustrate configuration examples of memory cells in which the access transistors of the memory cells are N-type transistors. FIG. 2A illustrates a cross section of a planar-type cell and FIG. 2B illustrates a cross section of a stack-type cell.

In FIG. 2A, an N-type well 102 is formed in a P-type substrate 101, and a P-type well 103 is formed in the N-type well 102. N-type diffusion layers 104, 105, 106 which will be a source or a drain of the access transistor are formed in the P-type well 103. The P-type substrate 101 is connected to a wire PSUB which is set to a ground level GND during operation via a conductive plug. The N-type well 102 is connected to a wire NWELL via a conductive plug. The P-type well 103 is connected to a wire PWELL via a conductive plug.

One ferroelectric capacitor 107 of the memory cell has one electrode connected to the N-type diffusion layer 104 via an top electrode TEL and a conductive plug and another electrode connected to a plate line PL via a conductive plug. Another ferroelectric capacitor 108 of the memory cell has one electrode connected to the N-type diffusion layer 106 via a top electrode TEL and a conductive plug and another electrode connected to a plate line PL via a conductive plug. The N-type diffusion layer 105 is connected to the bit line BL via a conductive plug. Gates of the one access transistor using the N-type diffusion layer 104, 105 as its source or drain and the other access transistor using the N-type diffusion layer 105, 106 as its source or drain are connected to different words lines WL.

In FIG. 2B, an N-type well 112 is formed in a P-type substrate 111, and a P-type well 113 is formed in the N-type well 112. N-type diffusion layers 114, 115, 116 which will be a source or a drain of the access transistor are formed in the P-type well 113. The P-type substrate 111 is connected to a wire PSUB which is set to a ground level GND during operation via a conductive plug. The N-type well 112 is connected to a wire NWELL which is set to a potential VDD during operation via a conductive plug. The P-type well 113 is connected to a wire PWELL via a conductive plug.

One ferroelectric capacitor 117 of the memory cell has one electrode connected to the N-type diffusion layer 114 via a conductive plug and another electrode connected to a plate line PL via a conductive plug. Another ferroelectric capacitor 118 of the memory cell has one electrode connected to the N-type diffusion layer 116 via a conductive plug and another electrode connected to a plate line PL via a conductive plug. The N-type diffusion layer 115 is connected to a bit line BL via a conductive plug. Gates of the one access transistor using the N-type diffusion layer 114, 115 as its source or drain and the other access transistor using the N-type diffusion layer 115, 116 as its source or drain are connected to different words lines WL.

In the memory cells illustrated in FIG. 2A and FIG. 2B, when data stored in the memory cells are erased, the cell well potential control circuit 24 sets the wires PWELL connected to the P-type wells 103, 113 to the potential VDD and sets the plate lines PL to the ground level GND as illustrated in FIG. 2A and FIG. 2B. The top electrodes TEL and the bit lines BL are in a floating state, and the word lines WL are at the ground level GND. By applying plus charges to the P-type well 103, 113 in this manner, a forward bias is applied to PN junctions between the P-type well 103,113 and the N-type diffusion layers 104, 106, 114, 116 and the potentials at the N-type diffusion layers 104, 106, 114, 116 become a potential corresponding to the potential VDD, thereby resetting polarization of the ferroelectric capacitors 107, 108, 117, 118 in one direction. This makes it possible to collectively erase the data stored in the memory cells.

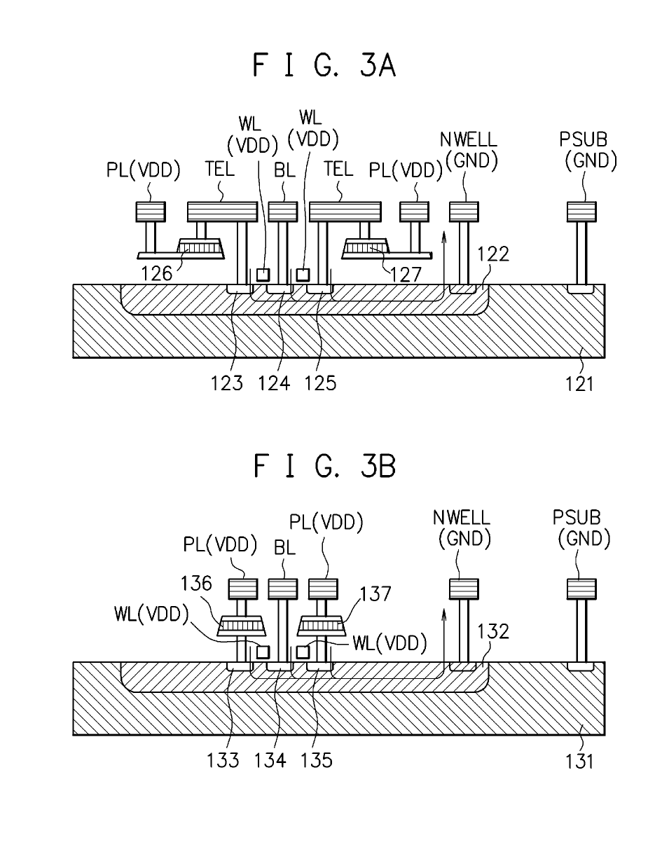

FIG. 3A and FIG. 3B are views illustrating configuration examples of memory cells in this embodiment. FIG. 3A and FIG. 3B illustrate configuration examples of memory cells in which the access transistors of the memory cells are P-type transistors. FIG. 3A illustrates a cross section of a planar-type cell and FIG. 3B illustrates a cross section of a stack-type cell.

In FIG. 3A, an N-type well 122 is formed in a P-type substrate 121. P-type diffusion layers 123, 124, 125 which will be a source or a drain of the access transistor are formed in the N-type well 122. The P-type substrate 121 is connected to a wire PSUB which is set to a ground level GND during operation via a conductive plug. The N-type well 122 is connected to a wire NWELL via a conductive plug.

One ferroelectric capacitor 126 of the memory cell has one electrode connected to the P-type diffusion layer 123 via a top electrode TEL and a conductive plug and another electrode connected to a plate line PL via a conductive plug. Another ferroelectric capacitor 127 of the memory cell has one electrode connected to the P-type diffusion layer 125 via a top electrode TEL and a conductive plug and another electrode connected to a plate line PL via a conductive plug. The P-type diffusion layer 124 is connected to a bit line BL via a conductive plug. Gates of the one access transistor using the P-type diffusion layer 123, 124 as its source or drain and the other access transistor using the P-type diffusion layer 124, 125 as its source or drain are connected to different words lines WL.

In FIG. 3B, an N-type well 132 is formed in a P-type substrate 131. P-type diffusion layers 133, 134, 135 which will be a source or a drain of the access transistor are formed in the N-type well 132. The P-type substrate 131 is connected to a wire PSUB which is set to a ground level GND during operation via a conductive plug. The N-type well 132 is connected to a wire NWELL via a conductive plug.

One ferroelectric capacitor 136 of the memory cell has one electrode connected to the P-type diffusion layer 133 via a conductive plug and another electrode connected to a plate line PL via a conductive plug. Another ferroelectric capacitor 137 of the memory cell has one electrode connected to the P-type diffusion layer 135 via a conductive plug and another electrode connected to a plate line PL via a conductive plug. The P-type diffusion layer 134 is connected to a bit line BL via a conductive plug. Gates of the one access transistor using the P-type diffusion layer 133, 134 as its source or drain and the other access transistor using the P-type diffusion layer 134, 135 as its source or drain are connected to different words lines WL.

In the memory cells illustrated in FIG. 3A and FIG. 3B, when data stored in the memory cells are erased, the cell well potential control circuit 24 sets the wires NWELL connected to the N-type wells 122, 132 to the potential GND and sets the plate lines PL to the potential VDD as illustrated in FIG. 3A and FIG. 3B. The top electrodes TEL and the bit lines BL are in a floating state, and the word lines WL are at the potential VDD. In this manner, a forward bias is applied to PN junctions between the N-type well 122, 132 and the P-type diffusion layers 123, 125, 133, 135, and the potentials at the P-type diffusion layers 123, 125, 133, 135 become a potential corresponding to the ground level GND, thereby resetting polarization of the ferroelectric capacitors 126, 127, 136, 137 in one direction. This makes it possible to collectively erase the data stored in the memory cells.

Note that a case where the access transistor is an N-type transistor will be described as an example in the following description. Further, a parasitic junction made by the PN junction between the N-type (P-type) diffusion layer which will be the source or the drain of the transistor and the P-type (N-type) well in this embodiment is illustrated by a diode as necessary hereinafter. Further, a square in the following drawings indicates that the ground level GND is supplied to the well (substrate) at all times.

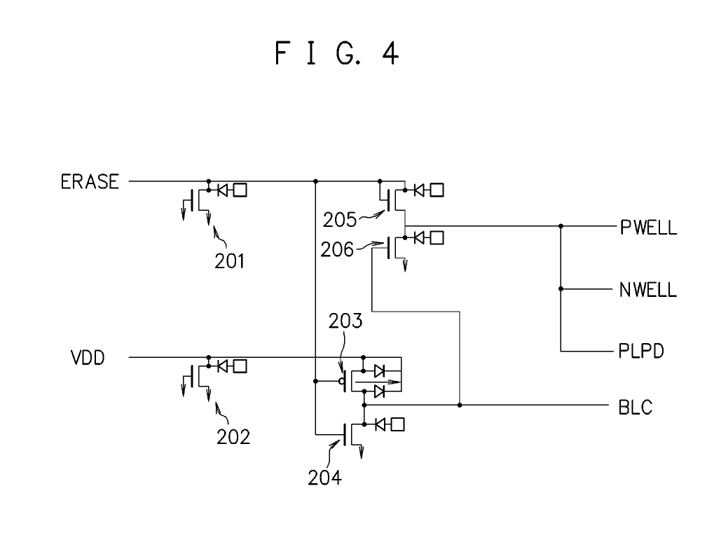

FIG. 4 is a diagram illustrating a configuration example of the cell well potential control circuit 24 in this embodiment. The purpose of this circuit is enabling ELASE regardless of when external VDD is supplied or is off. In FIG. 4, a wire ERASE and a wire VDD are connected to the terminal ERASE and a terminal VDD of the semiconductor memory device 10 respectively. N-type transistors 201, 202 are ESD (Electrostatic Discharge) resistant circuits for the wires ERASE, VDD respectively.

A P-type transistor 203 has a source connected to the wire VDD, a drain connected to a wire BLC, and a gate connected to the wire ERASE. An N-type well (N-type substrate) where the P-type transistor 203 is formed is connected to the potential VDD. An N-type transistor 204 has a source connected to the ground level GND, a drain connected to the wire BLC, and a gate connected to the wire ERASE.

An N-type transistor 205 has a gate and a drain both connected to the wire ERASE and a source connected to wires PWELL, NWELL, PLPD. An N-type transistor 206 has a source connected to the ground level GND, a drain connected to the wires PWELL, NWELL, PLPD, and a gate connected to the wire BLC.

In the case where the potential VDD is supplied to the wire ERASE, the cell well potential control circuit 24 sets the wires PWELL, NWELL, PLPD to the potential VDD regardless of the potential of the wire VDD and sets the wire BLC to the ground level GND. Accordingly, even when the semiconductor memory device 10 is in a power-off state, it is possible to set the wires PWELL, NWELL, PLPD to the potential VDD by supplying a certain potential (VDD when the access transistor is an N-type transistor) to the terminal ERASE, thereby collectively erasing the data stored in the memory cells even without external power supply. When the wire ERASE is at the ground level GND, the cell well potential control circuit 24 sets the wires PWELL, NWELL, PLPD to the ground level GND and sets the wire BLC to the voltage VDD.

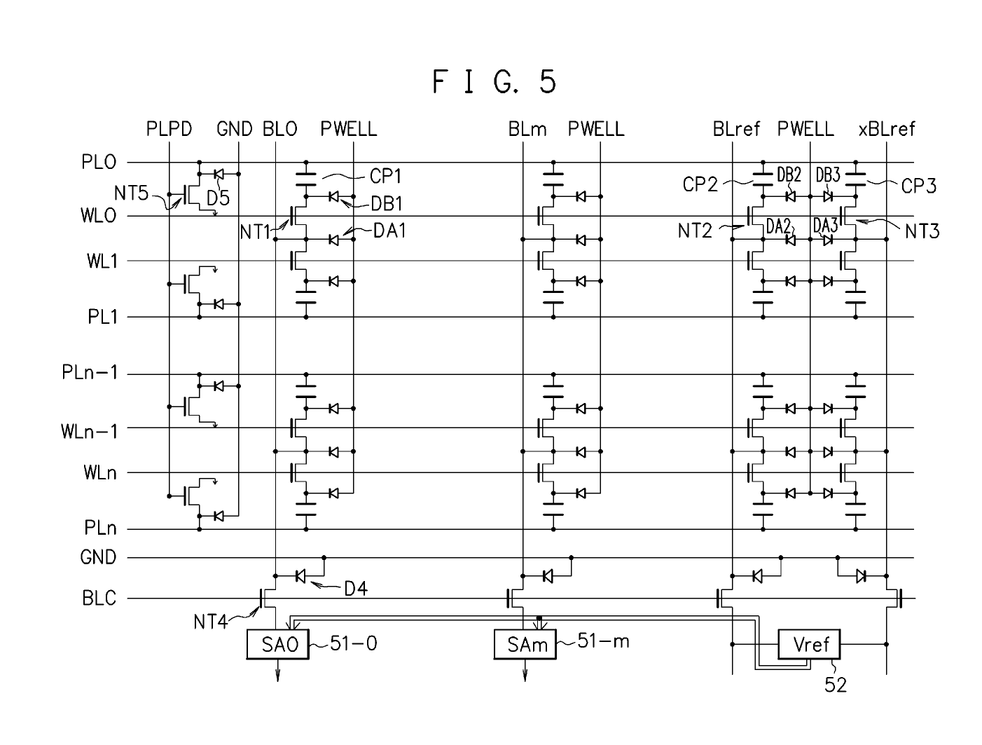

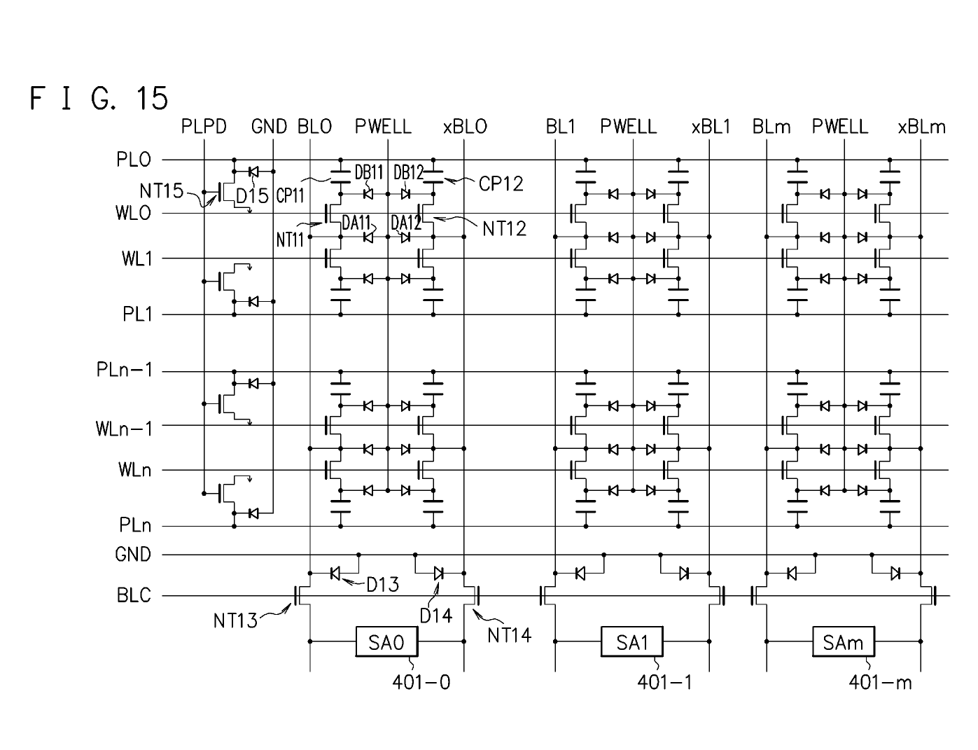

Hereinafter, embodiments of a method of erasing data in the semiconductor memory device in this embodiment will be described. Note that in the following description, only memory cells relating to data erasure and its peripheral circuits are illustrated, and description of the other configurations will be omitted because they are the same as in the prior art. Hereinafter, a cell being a memory cell having 1T1C (one transistor and one capacitor) will be described as an example in FIG. 5 to FIG. 14, and a cell being a memory cell having 2T2C (two transistors and two capacitors) will be described as an example in FIG. 15 to FIG. 20.

### First Embodiment

FIG. 5 is a diagram illustrating a configuration example of a semiconductor memory device according to a first embodiment of the present invention. In FIG. 5, each of memory cells storing data is connected to a bit line BLi (i is a subscript, i=0 to m (m is a natural number)). Further, memory cells that supply a reference potential for determining the data stored in the memory cells connected to the bit line BLi are connected to bit lines BLref, xBLref. Here, the bit lines BLref, xBLref are bit lines in a complementary relationship.

Each of the memory cells connected to the bit line BLi includes an access transistor NT1 and a ferroelectric capacitor CP1. Each ferroelectric capacitor CP1 has one electrode connected to a plate line PLj and another electrode connected to the bit line BLi via the access transistor NT1. In other words, the access transistor NT1 has a source and a drain one of which is connected to the bit line BLi and the other of which is connected to the other electrode of the ferroelectric capacitor CP1. A P-type well where the source or the drain of the access transistor NT1 is formed is connected to a wire PWELL via a diode DA1, DB1 being a parasitic junction.

One of the memory cells that supply the reference potential has an access transistor NT2 and a ferroelectric capacitor CP2, and the other memory cell has an access transistor NT3 and a ferroelectric capacitor CP3. The ferroelectric capacitor CP2 has one electrode connected to the plate line PLj and another electrode connected to the bit line BLref via the access transistor NT2. In other words, the access transistor NT2 has a source and a drain one of which is connected to the bit line BLref and the other of which is connected to the other electrode of the ferroelectric capacitor CP2. The access transistor NT3 has a source and a drain one of which is connected to the bit line xBLref (x representing a complementary signal line) and the other of which is connected to the other electrode of the ferroelectric capacitor CP3. The source or the drain of the access transistor NT2 is connected to the wire PWELL via a diode DA2, DB2 being a parasitic junction. The source or the drain of the access transistor NT3 is connected to the wire PWELL via a diode DA3, DB3 being a parasitic junction.

The bit line BLi (including the bit lines BLref and xBLref) to which each of the memory cells is connected is connected to a sense amplifier (SAi) 51-i via a transistor NT4 having a gate connected to the wire BLC. In erasing mode, the bit line BLi levels also increased to VDD level of the wire ELASE and the transistor NT4 prevents that the bit line BLi levels flow into sense amplifiers or other circuits by applying the GND level to the wire BLC. The transistor NT4 is formed in a well to which the ground level GND is supplied. A diode D4 is formed by a parasitic junction between the source or the drain of the transistor NT4 and the well where the source or the drain is formed. Each plate line PLj (j is a subscript, j=0 to n (n is a natural number)) is connected to the ground level GND via a transistor NT5 having a gate connected to a wire PLPD.

The sense amplifier 51-i senses charges read to the bit line BLi using an average of charges read from the memory cells (reference cells) connected to the bit line BLref and the bit line xBLref as a reference level, and outputs data. A reference level generation unit 52 generates the reference level on the basis of the charges read from the memory cells connected to the bit line BLref and the bit line xBLref, and outputs it. Note that in a normal operation, the memory cell connected one of the bit lines BLref and xBLref is controlled to be in a P-polarization direction illustrated in FIG. 22 (located at a lower intersection point on a Q-axis, and polarization-inverted in reading by applying + (plus) potential to the plate line PL to output many charges to the bit line), and the memory cell connected to other bit line of them is controlled to be in a U-polarization direction illustrated in FIG. 22 (located at an upper intersection point on the Q-axis, and not polarization-inverted in reading by applying + (plus) potential to the plate line PL).

According to the semiconductor memory device in the first embodiment, each of the memory cells is formed in a well whose potential is controlled according to the voltage to be inputted into the terminal ERASE, namely, a well to which the wire PWELL is connected. Thus, supplying the potential VDD to the terminal ERASE makes it possible to set the potential of the plate line PLj connected to one electrode of the ferroelectric capacitor CP1 to CP3 of the memory cell to the ground level GND and set the potential of the P-type well connected to the other electrode of the ferroelectric capacitor CP1 to CP3 to the potential VDD. This results in states as illustrated in FIG. 2A and FIG. 2B, in which any of the ferroelectric capacitors CP1 to CP3 of the memory cells is brought into a P-polarization state illustrated in FIG. 22 (lower intersection point on the Q-axis) and can output indefinite data in reading data and realize data erasure in a short time. In this case, both of Vref and DATA cells are determined to be either “0” data or “1” data depending on variations of the sense amplifier because all DATA cells and both positive and negative reference cells are the P-polarization, resulting in Vref level of P-polarization and the same BLi levels of each p-polarization DATA cells are compared at the sense amplifier and it outputs indefinite level output. It is only necessary to provide a pull-down circuit that sets the plate line PLj to the ground level GND in erasing data and the cell well potential control circuit 24 as illustrated in FIG. 4 as additional circuits, so that an increase in circuit area can also be suppressed.

Note that in the semiconductor memory device illustrated in FIG. 5 (similarly to semiconductor memory devices in other embodiments), the memory cell connected to one of the bit line BLref and the bit line xBLref is brought into the P-polarization state illustrated in FIG. 22 (lower intersection point on the Q-axis) and the memory cell connected to the other of them is brought into the U-polarization state (upper intersection point on the Q-axis) in a normal operation. In reading data from the memory cell, for example, non-selected word line WLj and plate line PLj are set to the ground level GND and selected word line WLj and plate line PLj are set to the potential VDD. This changes the potential of the bit line BLi correspondingly to the charges according to the data stored in the memory cell corresponding to the selected word line WLj and plate line PLj so as to read the data. In this case, the level of Vref (the reference level) is average of p-polarization and u-polarization and compared with levels of DATA cells either p-polarization or u-polarization at sense amplifier. In writing data, a word line WLj and a plate line PLj of a memory cell into which data is to be written are set to the potential VDD and the potential of a bit line BLi is set to the ground level GND so as to perform U-writing, and the potentials of the word line WLj and the bit line BLi are set to VDD and the potential of the plate line PLj is set to GND so as to perform P-writing. These are achieved by a general operation by starting the word line, setting the potential of the bit line to VDD or GND, and driving the plate line in a pulse state (raising it to VDD to provide a U-writing period, and lowering it to GND to provide a P-writing period).

### Second Embodiment

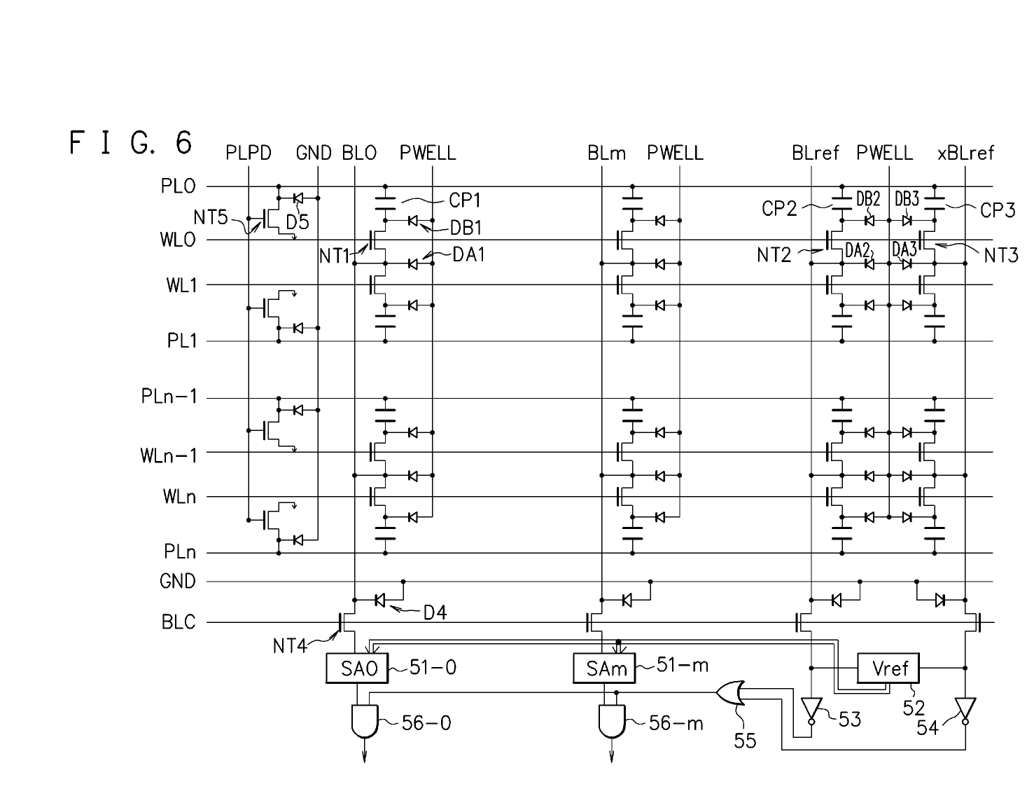

FIG. 6 is a diagram illustrating a configuration example of a semiconductor memory device according to a second embodiment. Components in FIG. 6 having the same functions as the components illustrated in FIG. 5 are given the same reference numerals, and overlapped description thereof will be omitted.

In FIG. 6, level detection circuits 53, 54 detect whether or not the voltages to be outputted to the respective bit line BLref and bit line xBLref are voltages at which the memory cells correspond to the P-polarization. The level detection circuits 53 and 54 output low level when the voltages outputted to the bit line BLref and the bit line xBLref are voltages at which the memory cells correspond to the P-polarization.

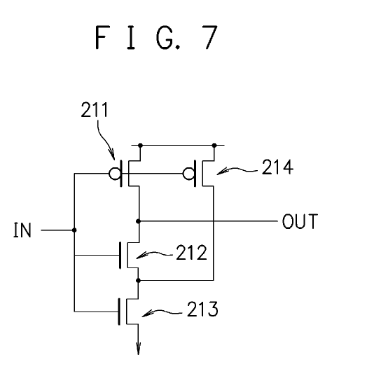

To the level detection circuits 53 and 54, for example, a Schmitt trigger circuit illustrated in FIG. 7 is applicable. The Schmitt trigger circuit illustrated in FIG. 7 is configured such that a P-type transistor 211 and N-type transistors 212, 213 having gates supplied with an input signal IN are connected in series between the voltage VDD and the ground level. GND, and a P-type transistor 214 having a gate supplied with the input signal IN has a source connected to the voltage VDD and a drain connected to an interconnection point of the N-type transistors 212, 213. The potential of an interconnection point of the P-type transistor 211 and the N-type transistor 212 is outputted as an output signal OUT. The output signal OUT is changed to low level when the input signal IN becomes higher than a first threshold value, and the output signal OUT is changed to high level when the input signal IN becomes lower than a second threshold value.

A logical sum operation circuit (OR circuit) 55 receives the outputs of the level detection circuits 53, 54 and outputs an operation result of them. The output of the OR circuit 55 is inputted into a logical product operation circuit (AND circuit) 56-i to which the output of the sense amplifier 51-i is inputted. The AND circuit 56-i outputs a logical product operation result of the outputs of the sense amplifier 51-i and the OR circuit 55.

According to the semiconductor memory device in the second embodiment, each of the memory cells is formed in a well whose potential is controlled according to the voltage to be inputted into the terminal ERASE and the potential VDD is supplied to the terminal ERASE, thereby making it possible to set the potential of the plate line PLj connected to one electrode of the ferroelectric capacitor CP1 to CP3 of the memory cell to the ground level GND and set the potential of the P-type well connected to the other electrode of the ferroelectric capacitor CP1 to CP3 to the potential VDD. This results in states as illustrated in FIG. 2A and FIG. 2B, in which any of the ferroelectric capacitors CP1 to CP3 of the memory cells is brought into a P-polarization state illustrated in FIG. 22 (lower intersection point on the Q-axis) and can realize data erasure in a short time. Further, the level detection circuits 53, 54 detect that the voltages outputted to the bit line BLref and the bit line xBLref are voltages at which the memory cells correspond to the P-polarization and output low level, and thereby can output all words as “0” data to the outside. It is only necessary to provide a pull-down circuit that sets the plate line PLj to the ground level GND in erasing data and the cell well potential control circuit 24 as illustrated in FIG. 4 as additional circuits, so that an increase in circuit area can also be suppressed. It is possible to perform collective erasure with the structure of a unit cell kept as it is and without an increase in area due to the addition of MOS and the like.

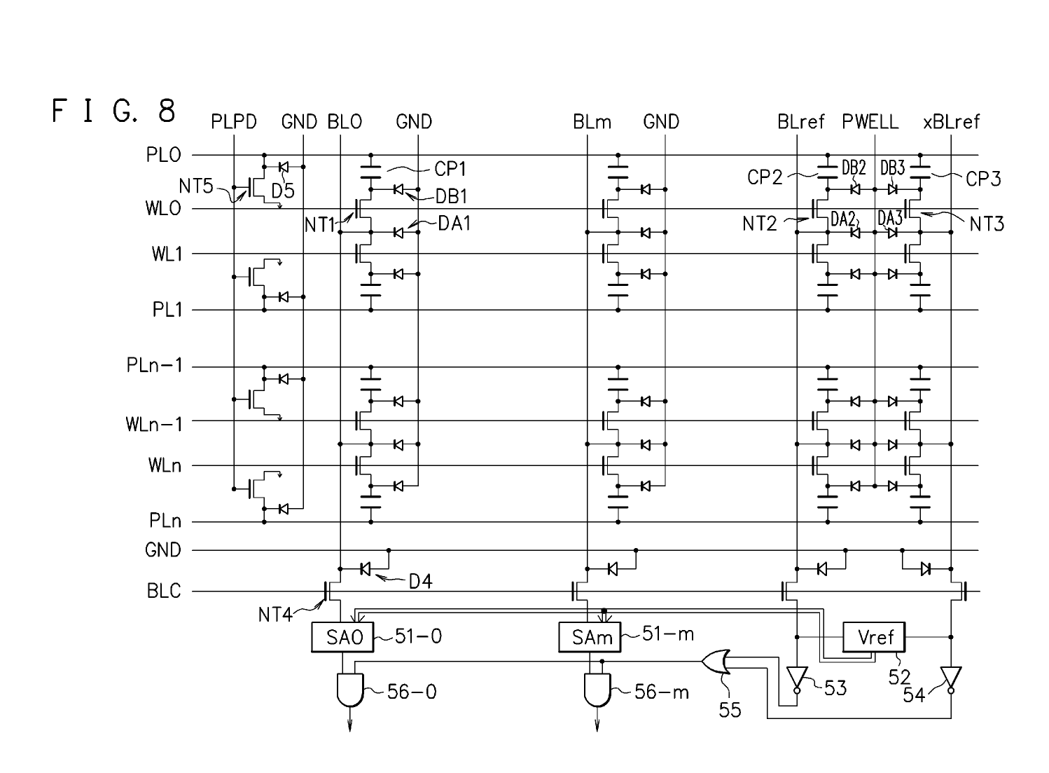

Note that since it is only necessary that the memory cells for outputting the reference potential are reset in the P-polarization direction in erasing data in the second embodiment, only the memory cells connected to the bit line BLref and the bit line xBLref may be formed in the wells whose potentials are controlled according to the voltage inputted into the terminal ERASE and other memory cells may be formed in the P-type wells to which the ground level GND is supplied at all times, for instance, as illustrated in FIG. 8. This makes it possible to reduce the number of memory cells performing data erasure and reduce the charging capacity and power consumption relating to the data erasure. Further, by setting the read data to U(0) by the logical product operation circuit 56 in terms of operation of an FeRAM that normally performs read and rewrite, U(0) is automatically rewritten into the cells by rewrite, thereby sequentially achieving erasure for all area other than Vref cells (flag cells).

### Third Embodiment

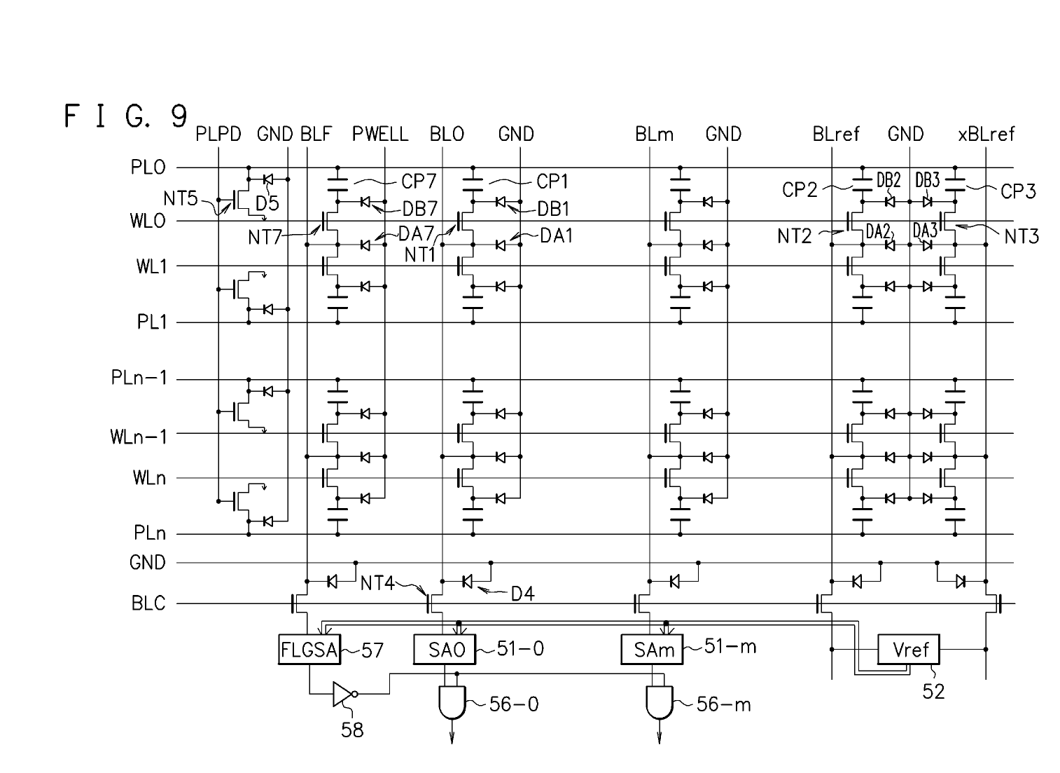

FIG. 9 is a diagram illustrating a configuration example of a semiconductor memory device according to a third embodiment. Components in FIG. 9 having the same functions as the components illustrated in FIG. 5 are given the same reference numerals, and overlapped description thereof will be omitted. The semiconductor memory device in the third embodiment is configured such that flag cells connected to a bit line BLF are provided, the flag cells connected to the bit line BLF are brought into the P-polarization state by applying voltage thereto as illustrated in FIG. 2A and FIG. 2B in erasing data, and the flag cells connected to the bit line BLF are brought into the U-polarization state in a normal operation. Thus, high level signal is outputted from a flag sense amplifier 57 and low level signal is outputted from an inverter 58 in erasing data, and low level signal is outputted from the flag sense amplifier 57 and high level signal is outputted from the inverter 58 in a normal operation.

According to the third embodiment, since it is only necessary to reset the polarization direction the flag cells connected to the bit line BLF, it is possible to realize data erasure in a short time and also suppress an increase in circuit area. Further, it is only necessary to perform erasure only for the flag cells connected to one bit line BLF, it is possible to reduce the power consumption relating to the data erasure.

In addition, in the FIG. 9 configuration of sense amplifiers operate stable both in erasing and in normal mode, since stable Vref level of average of p-polarization and u-polarization is supplied always also for the flag sense amplifier 57 to compare.

### Fourth Embodiment

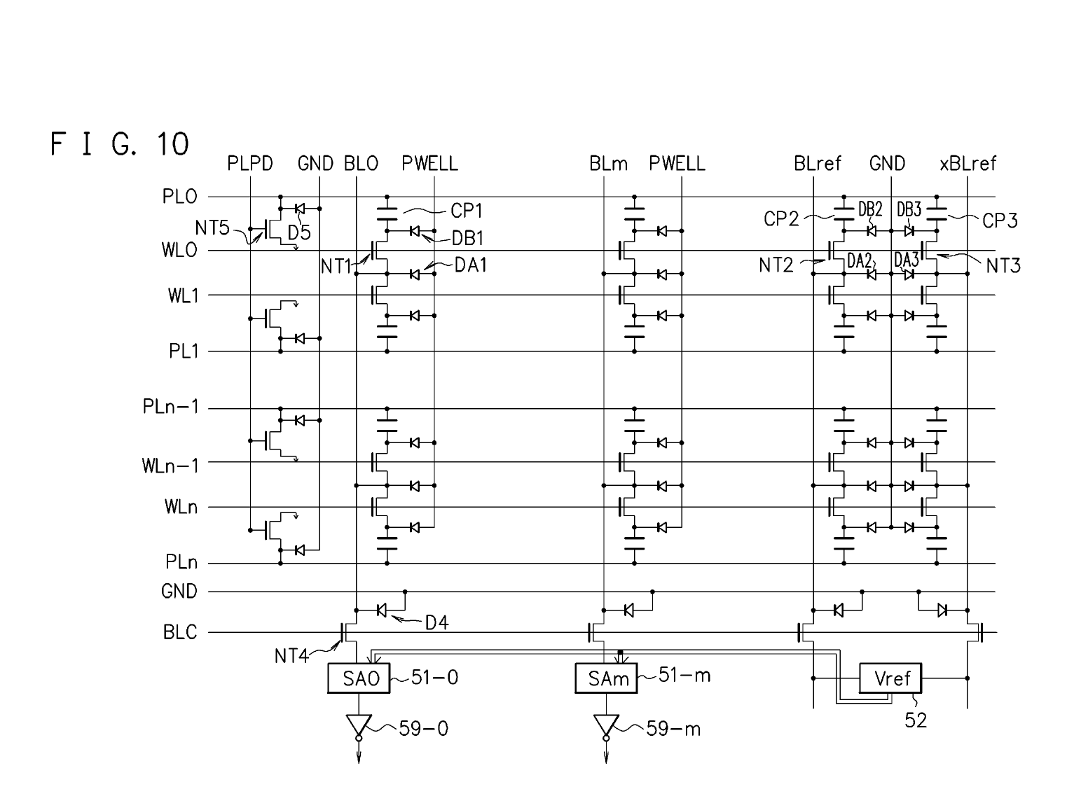

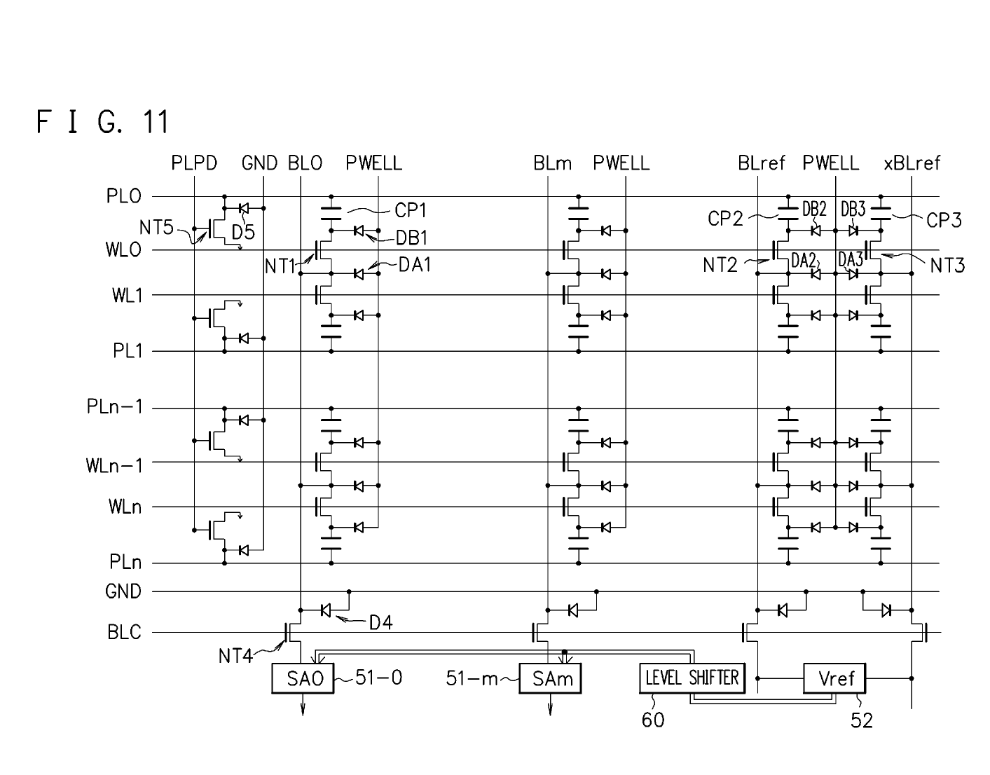

FIG. 10 is a diagram illustrating a configuration example of a semiconductor memory device according to a fourth embodiment. Components in FIG. 10 having the same functions as the components illustrated in FIG. 5 are given the same reference numerals, and overlapped description thereof will be omitted. The semiconductor memory device in the fourth embodiment is configured such that memory cells that actually store data are formed in wells whose potentials are controlled according to the voltage to be inputted into the terminal ERASE, namely, wells to which the wire PWELL is connected as illustrated in FIG. 10. Further, memory cells that supply the reference potential are formed in P-type wells set to the ground level during operation.

Thus, the average of charges of the memory cells (reference cells) connected to the bit line BLref and the bit line xBLref is outputted as a reference level. After the data erasure is performed, a voltage according to the P-polarization is read to the bit line BLi, and the sense amplifier 51-i outputs a high level signal. Accordingly, the output of the sense amplifier 51-i is outputted via an inverter 59-i, and thereby can output all words as “0” data to the outside.

In the FIG. 10 configuration, in the normal mode, all the DATA cells of capacitor CPi stores inverted DATA that is written from outside of the device for align data polarity because always sense data is inverted by inverter 59-i to output.

### Fifth Embodiment

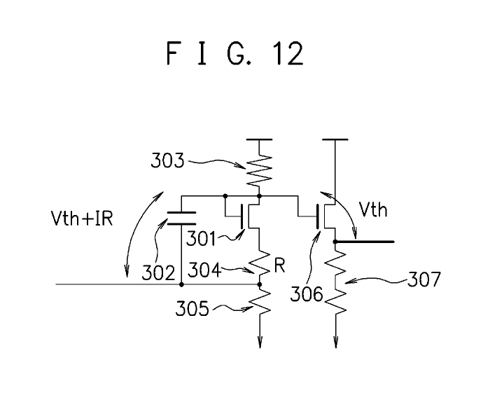

FIG. 11 is a diagram illustrating a configuration example of a semiconductor memory device according to a fifth embodiment. Components in FIG. 11 having the same functions as the components illustrated in FIG. 5 are given the same reference numerals, and overlapped description thereof will be omitted. The semiconductor memory device in the fifth embodiment is configured such that a level shifter circuit 60 as illustrated in FIG. 12 is provided to apply offset to a plus side with respect to the reference level outputted from the reference level generation unit 52. Thus, the potential of the bit line BLi by the memory cell after data erasure in reading data becomes lower than the reference level and “0” data can be outputted as read data to the outside. Note that the offset amount by the level shifter circuit 60 is set not to influence the sense margin in a normal operation.

The level shifter circuit 60 illustrated in FIG. 12 includes N-type transistors 301, 306, a capacitor 302, and resistors 303, 304, 305, 307. The N-type transistor 301 has a gate and a drain both connected to one electrode of the capacitor 302 and a source connected to the ground level via series resistors 304, 305. The gate and the drain of the N-type transistor 301 are also connected to the voltage VDD via the resistor 303. Another electrode of the capacitor 302 and an interconnection point of the series resistors 304, 305 are connected a first input/output node of the level shifter circuit. The N-type transistor 306 has a gate connected to the one electrode of the capacitor 302 and a drain connected to the voltage VDD. The N-type transistor 306 has a source connected to the ground level via the resistor 307. An interconnection point of the source of the N-type transistor 306 and the resistor 307 is connected a second input/output node of the level shifter circuit.

### Sixth Embodiment

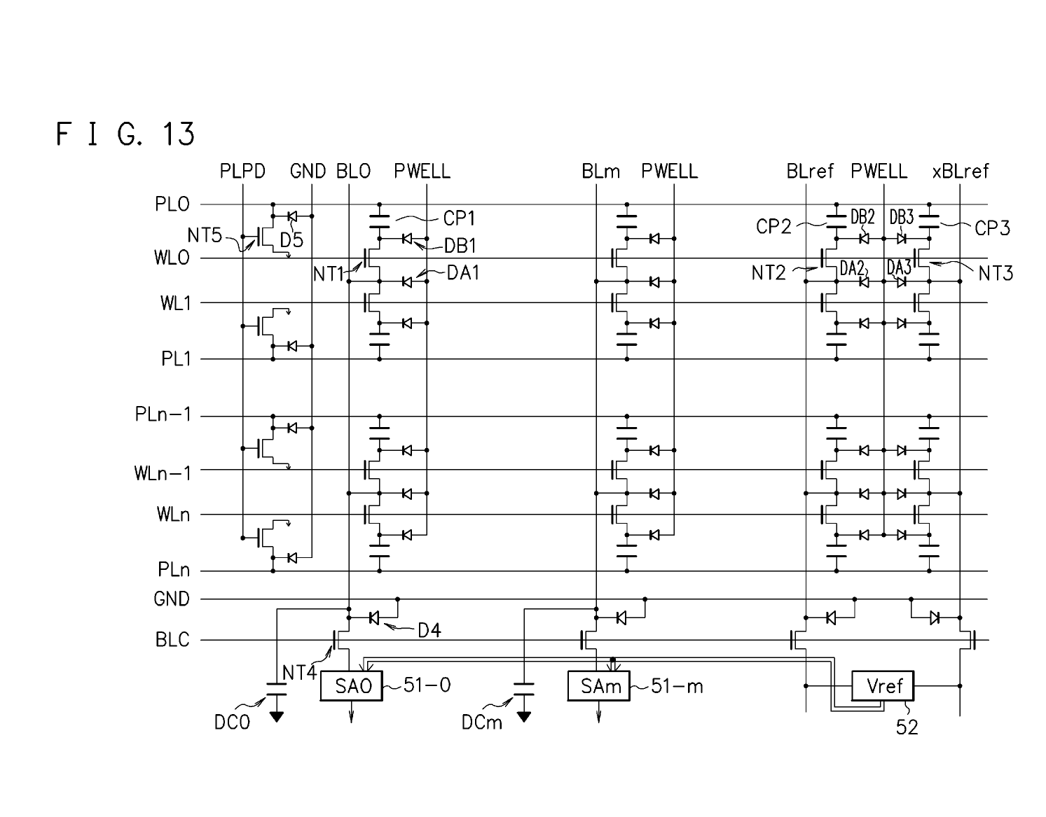

FIG. 13 is a diagram illustrating a configuration example of a semiconductor memory device according to a sixth embodiment. Components in FIG. 13 having the same functions as the components illustrated in FIG. 5 are given the same reference numerals, and overlapped description thereof will be omitted. The semiconductor memory device in the sixth embodiment is configured such that a dummy capacitor DCi is connected to the bit line BLi connected with memory cells that actually store data to make the load on the bit line BLi larger than the loads on the bit line BLref and the bit line xBLref.

Thus, the potential of the bit line BLi to which the memory cells that store data are connected after erasing data becomes lower than the reference level outputted from the reference level generation unit 52, and “0” data can be outputted as read data to the outside.

### Seventh Embodiment

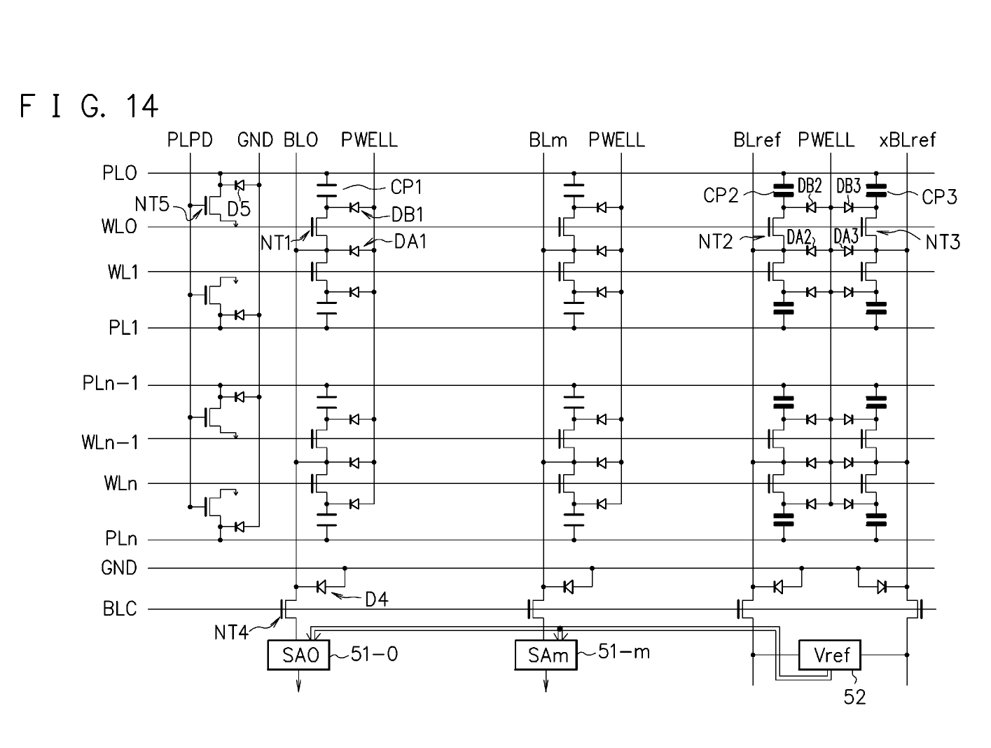

FIG. 14 is a diagram illustrating a configuration example of a semiconductor memory device according to a seventh embodiment. Components in FIG. 14 having the same functions as the components illustrated in FIG. 5 are given the same reference numerals, and overlapped description thereof will be omitted.

In FIG. 13, the dummy capacitor DCi is connected to the bit line BLi to make the load on the bit line BLi larger than the loads on the bit line BLref and the bit line xBLref. In contrast, in FIG. 14, the capacities of the ferroelectric capacitors of the memory cells connected to the bit line BLref and the bit line xBLref that supply the reference potential are made larger than the capacity of the ferroelectric capacitor of the memory cell connected to the bit line BLi and thereby can make the reference level in reading data after data erasure higher than the potential of the bit line BLi. Accordingly, “0” data can be outputted as read data to the outside.

### Eighth Embodiment

FIG. 15 is a diagram illustrating a configuration example of a semiconductor memory device according to an eighth embodiment. In FIG. 15, each of the memory cells that store data is a 2T2C (two transistors and two capacitors) type memory cell, and connected to the bit line BLi or a complementary bit line xBLi.

Each of the memory cells connected to the bit line BLi has an access transistor NT11 and a ferroelectric capacitor CP11. Each ferroelectric capacitor CP11 has one electrode connected to a plate line PLj and another electrode connected to a bit line BLi via the access transistor NT11. In other words, the access transistor NT11 has a source and a drain one of which is connected to the bit line BLi and the other of which is connected to the other electrode of the ferroelectric capacitor CP11. A P-type well where the source or the drain of the access transistor NT11 is formed is connected to a wire PWELL via a diodes DA11, DB11 being a parasitic junction.

Similarly, each of memory cells connected to the complementary bit line xBLi has an access transistor NT12 and a ferroelectric capacitor CP12. Each ferroelectric capacitor CP12 has one electrode connected to the plate line PLj and another electrode connected to the bit line xBLi via the access transistor NT12. In other words, the access transistor NT12 has a source and a drain one of which is connected to the bit line xBLi and the other of which is connected to the other electrode of the ferroelectric capacitor CP12. A P-type well where the source or the drain of the access transistor NT12 is formed is connected to the wire PWELL via a diode DA12, DB12 being a parasitic junction.

The bit line BLi to which the memory cells are connected is connected to a sense amplifier (SAi) 401-i via a transistor NT13 having a gate connected to the wire BLC. Similarly, the bit line xBLi to which the memory cells are connected is connected to the sense amplifier (SAi) 401-i via a transistor NT14 having a gate connected to the wire BLC. The transistors NT13, NT14 is formed in a well to which the ground level GND is supplied. The diode D13, D14 is made by a parasitic junction between the source or the drain of the transistor NT13, NT14 and the well where the source or the drain is formed.

Each plate line PLj (j is a subscript, j=0 to n (n is a natural number)) is connected to the ground level GND via a transistor NT15 having a gate connected to a wire PLPD. The sense amplifier 401-i senses a differential potential between the bit line BLi and the bit line xBLi and outputs data. Here, the memory cell connected to one of the bit lines BLi and xBLi is controlled to be in the P-polarization direction (referring FIG. 22, located at the lower intersection point on the Q-axis in reading, moving to an upper right point therefrom by applying + (plus) voltage to the plate line PL, polarization-inverted to output many charges to the bit line), and the memory cell connected to other bit line is controlled to be in the U-polarization direction illustrated in FIG. 22 (located at the upper intersection point on the Q-axis in reading, moving to the upper right point therefrom by applying + (plus) voltage to the plate line PL, and not polarization-inverted to output few charges to the bit line).

According to the semiconductor memory device in the eighth embodiment, each of the memory cells is formed in a well whose potential is controlled according to the voltage to be inputted into the terminal ERASE, namely, a well to which the wire PWELL is connected. Thus, supplying the potential VDD to the terminal ERASE makes it possible to set the potential of the plate line PLj connected to one electrode of the ferroelectric capacitor CP11, CP12 of the memory cell to the ground level GND and set the potential of the P-type well connected to the other electrode of the ferroelectric capacitor CP11, CP12 to the potential VDD. This results in states as illustrated in FIG. 2A and FIG. 2B, in which any of the ferroelectric capacitors CP11, CP12 of the memory cells is brought into the P-polarization state illustrated in FIG. 22 (lower intersection point on the Q-axis) and can output indefinite data in reading data and realize data erasure in a short time. It is only necessary to provide a pull-down circuit that sets the plate line PLj to the ground level GND in erasing data and the cell well potential control circuit 24 as illustrated in FIG. 4 as additional circuits, so that an increase in circuit area can also be suppressed.

### Ninth Embodiment

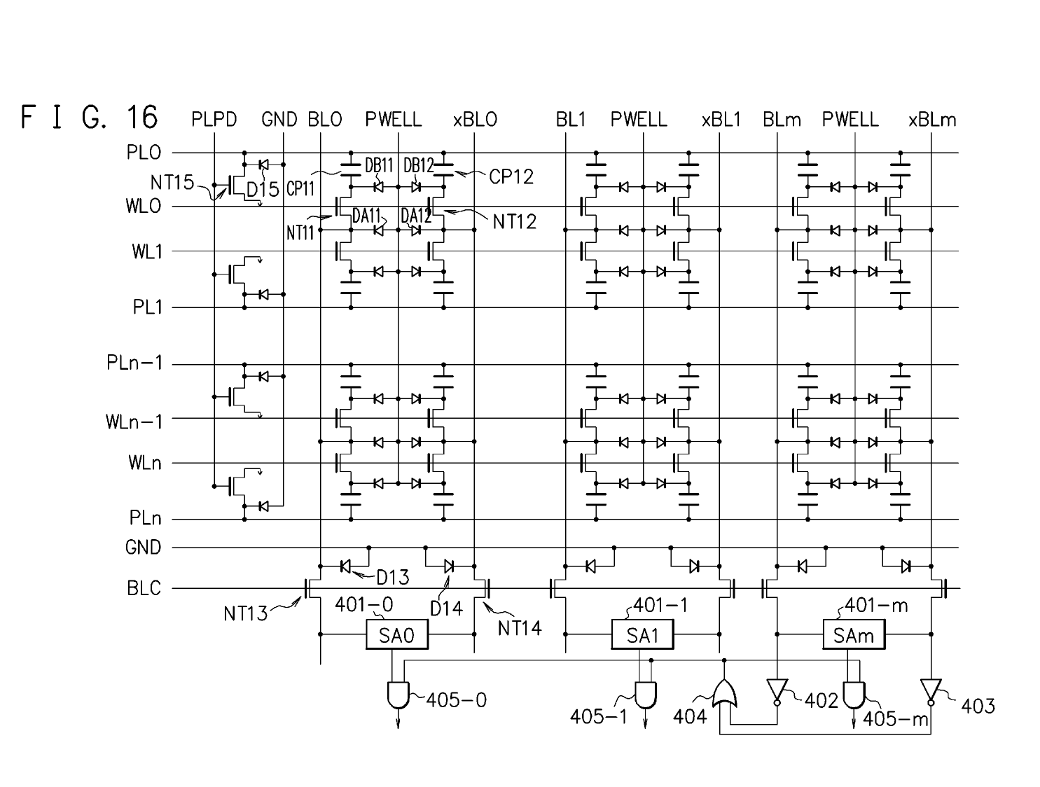

FIG. 16 is a diagram illustrating a configuration example of a semiconductor memory device according to a ninth embodiment. Components in FIG. 16 having the same functions as the components illustrated in FIG. 15 are given the same reference numerals, and overlapped description thereof will be omitted. In FIG. 16, level detection circuits 402 and 403 detect whether or not the voltages to be outputted to the respective bit line BLm and bit line xBLm are voltages at which the memory cells correspond to the P-polarization. To the level detection circuits 402 and 403, for example, the Schmitt trigger circuit illustrated in FIG. 7 is applicable, and the level detection circuits 402 and 403 output low level when the voltages outputted to the bit line BLm and bit line xBLm are voltages at which the memory cells correspond to the P-polarization.

An OR circuit 404 receives the outputs of the level detection circuits 402 and 403 and outputs an operation result of them. The output of the OR circuit 404 is inputted into an AND circuit 405-i to which the output of the sense amplifier 401-i is inputted. The AND circuit 405-i outputs a logical product result of the outputs of the sense amplifier 401-i and the OR circuit 404.

According to the semiconductor memory device in the ninth embodiment, each of the memory cells is formed in a well whose potential is controlled according to the voltage to be inputted into the terminal ERASE and the potential VDD is supplied to the terminal ERASE, thereby making it possible to set the potential of the plate line PLj connected to one electrode of the ferroelectric capacitor CP11, CP12 of the memory cell to the ground level GND and set the potential of the P-type well connected to the other electrode of the ferroelectric capacitor CP11, CP12 to the potential VDD. This results in states as illustrated in FIG. 2A and FIG. 2B, in which any of the ferroelectric capacitors CP11, CP12 of the memory cells is brought into the P-polarization state illustrated in FIG. 22 (lower intersection point on the Q-axis) and can realize data erasure in a short time. Further, the level detection circuits 402, 403 detect that the voltages outputted to the bit line BLm and the bit line xBLm are voltages at which the memory cells correspond to the P-polarization and output low level, and thereby can output all words as “0” data to the outside.

Though the voltages outputted to the bit line BLm and the bit line xBLm are detected by the level detection circuits 402 and 403 in FIG. 16, the voltages outputted to the other bit line BLi and bit line xBLi may be detected by the level detection circuits 402 and 403.

### Tenth Embodiment

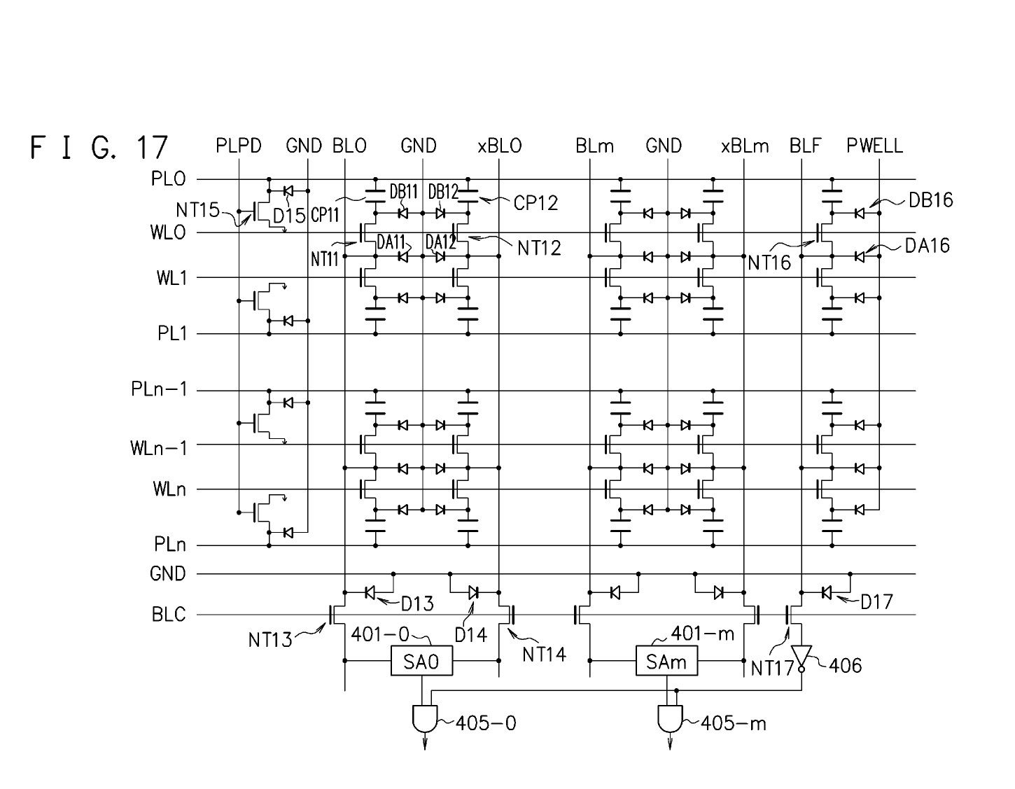

FIG. 17 is a diagram illustrating a configuration example of a semiconductor memory device according to a tenth embodiment. Components in FIG. 17 having the same functions as the components illustrated in FIG. 15 are given the same reference numerals, and overlapped description thereof will be omitted. The semiconductor memory device in the tenth embodiment is configured such that flag cells connected to a bit line BLF are provided, the flag cells connected to the bit line BLF are brought into the P-polarization state by applying voltage thereto as illustrated in FIG. 2A and FIG. 2B in erasing data, and the flag cells connected to the bit line BLF are brought into the U-polarization state in a normal operation. Further, a level detection circuit 406 is provided which outputs a low level signal when the voltage outputted to the bit line BLF is a voltage corresponding to the P-polarization and outputs a high level signal when the voltage outputted to the bit line BLF is a voltage corresponding to the U-polarization. Thus, the level detection circuit 406 outputs a low level signal in erasing data and outputs a high level signal in a normal operation, Accordingly, with the logical product of AND circuit 405-i, “0” data is outputted to the outside in erasing data and the stored data is outputted in a normal operation.

### Eleventh Embodiment

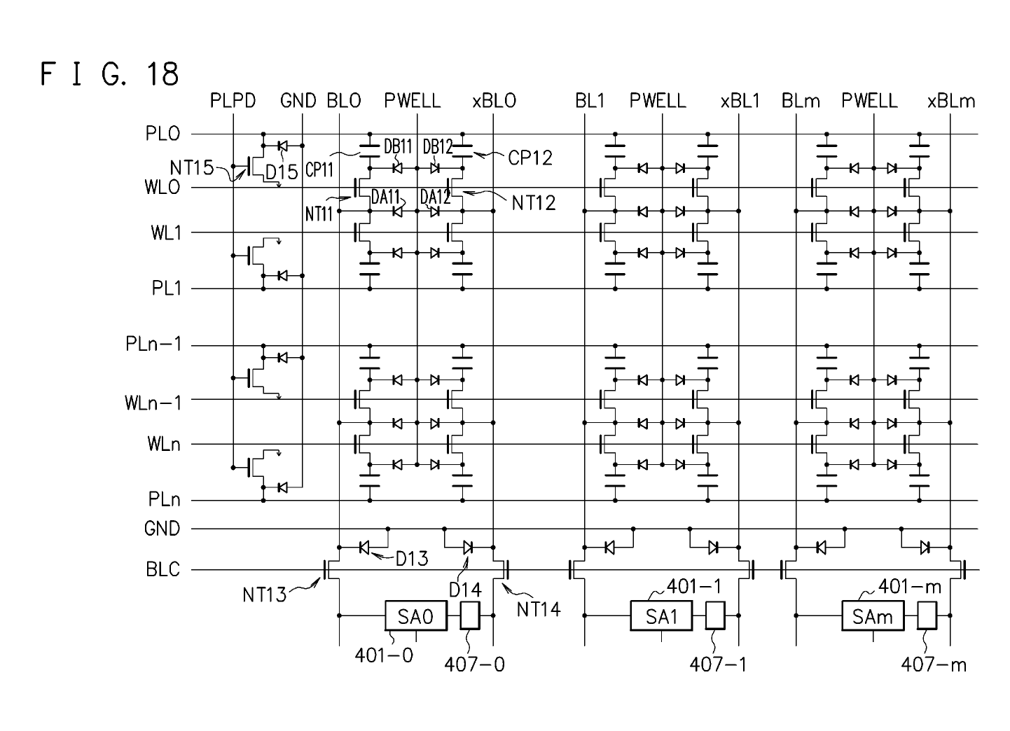

FIG. 18 is a diagram illustrating a configuration example of a semiconductor memory device according to an eleventh embodiment. Components in FIG. 18 having the same functions as the components illustrated in FIG. 15 are given the same reference numerals, and overlapped description thereof will be omitted. The semiconductor memory device in the eleventh embodiment is configured such that a level shifter circuit 407-i as illustrated in FIG. 12 is provided to apply offset to a plus side with respect to the voltage outputted from the bit line xBLi. More specifically, since both of the memory cells connected to the bit line pair BLi, xBLi are reset to the P-polarization in erasing data, the offset is applied to the plus side with respect to the voltage outputted from the bit line xBLi, so that the sense amplifier 401-i will output “0” data to the outside.

### Twelfth Embodiment

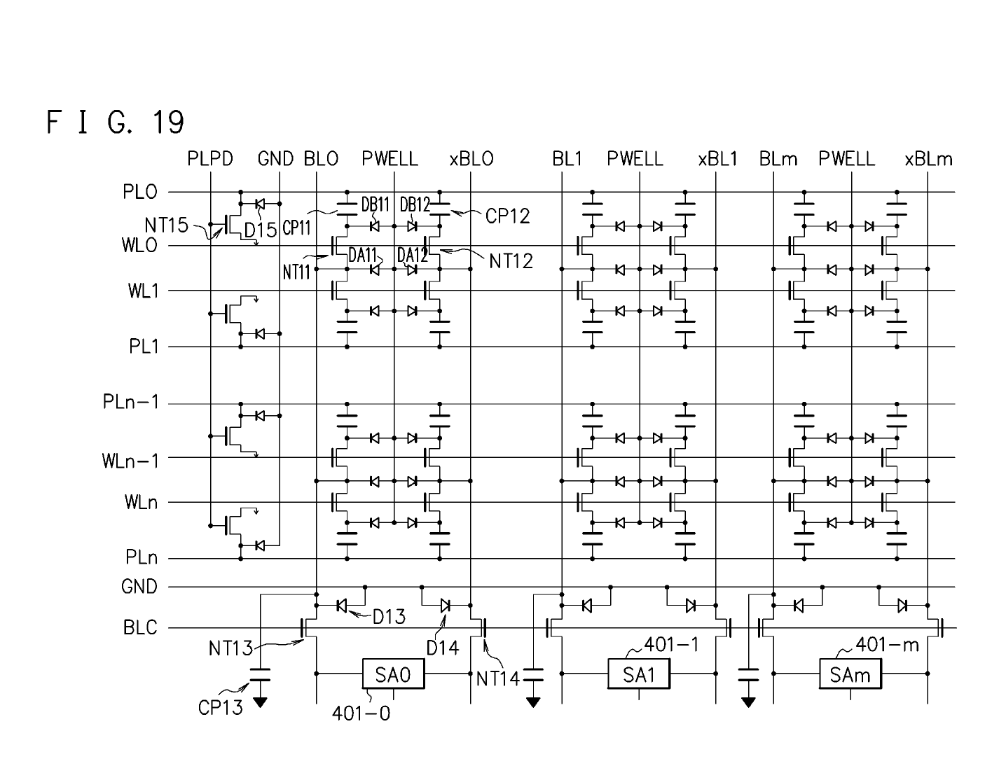

FIG. 19 is a diagram illustrating a configuration example of a semiconductor memory device according to a twelfth embodiment. Components in FIG. 19 having the same functions as the components illustrated in FIG. 15 are given the same reference numerals, and overlapped description thereof will be omitted. The semiconductor memory device in the twelfth embodiment is configured such that a capacitor CP13 is connected to the bit line BLi on the plus side to make the load on the bit line BLi larger than the load on the bit line xBLi. Thus, after data is erased and both the memory cells are reset to the P-polarization, the potential increase of the bit line BLi by the memory cell becomes smaller than the potential increase of the bit line xBLi and the sense amplifier 401-i will output “0” data as read data to the outside.

### Thirteenth Embodiment

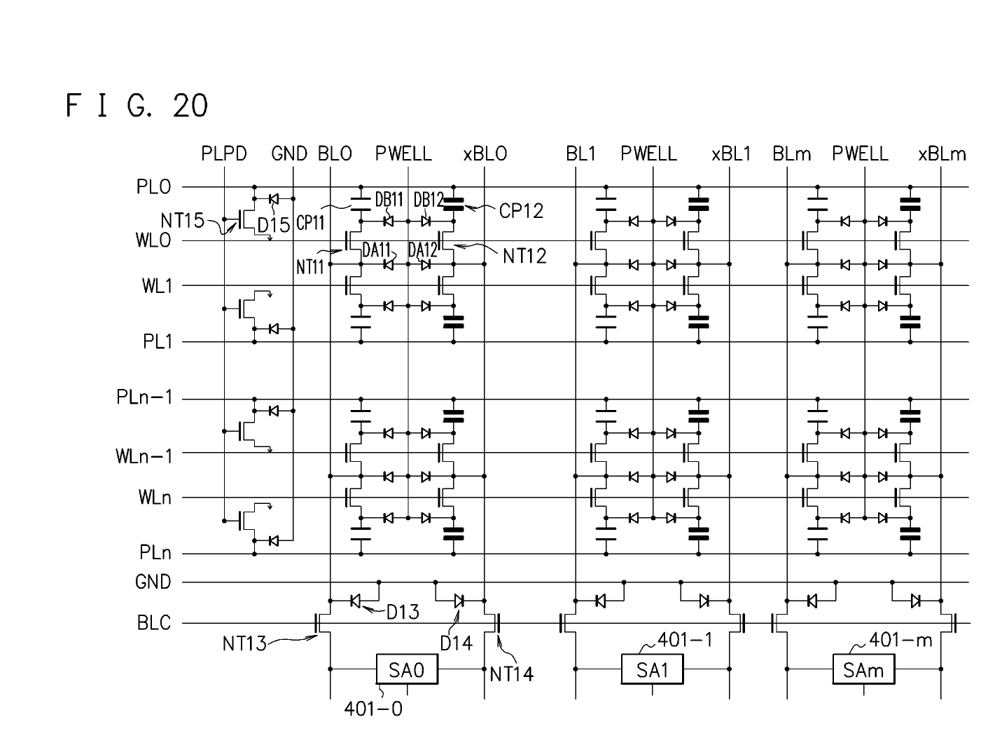

FIG. 20 is a diagram illustrating a configuration example of a semiconductor memory device according to a thirteenth embodiment. Components in FIG. 20 having the same functions as the components illustrated in FIG. 15 are given the same reference numerals, and overlapped description thereof will be omitted.

In FIG. 19, the capacitor CP13 is connected to the bit line BLi to make the load on the bit line BLi larger than the load on the bit line xBLi. In contrast, as illustrated in FIG. 20, the capacitor of the memory cell connected to the bit line xBLi is made larger than the capacitor of the memory cell connected to the bit lines BLi and thereby can make the potential of the bit line BLi in reading data after data erasure lower than the potential of the bit line xBLi. Accordingly, “0” data can be outputted from the sense amplifier 401-i as read data to the outside.

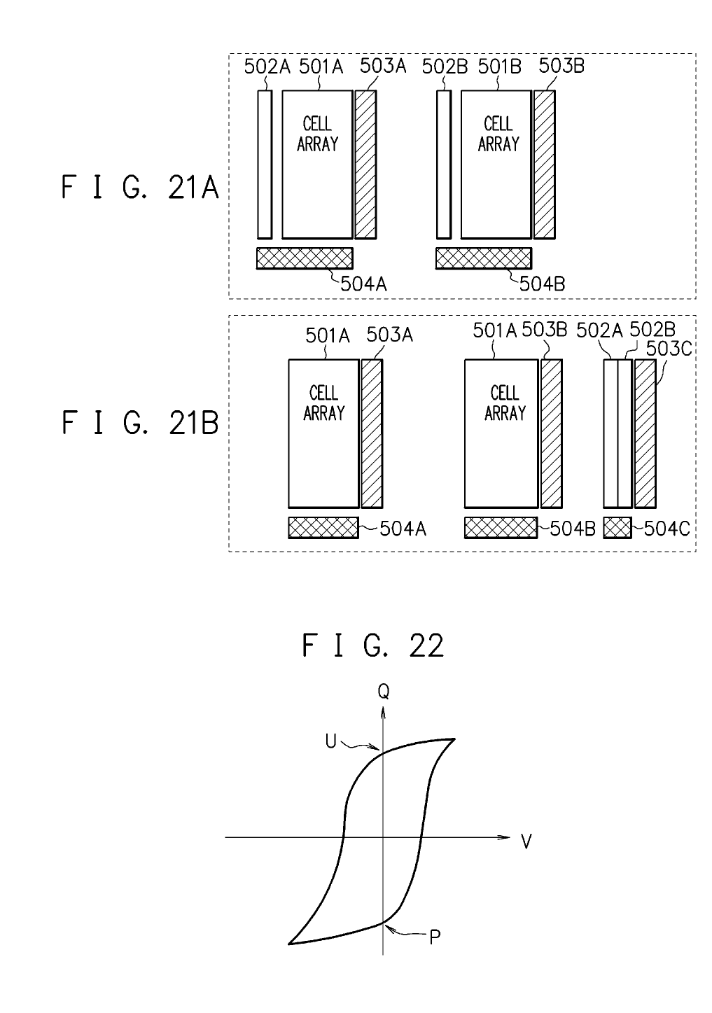

Note that in each of the above-described embodiments, wells where memory cells being erasure targets are formed may be arranged in a dispersed manner as illustrated in FIG. 21A, and may be arranged together in a certain region as illustrated in FIG. 21B. In FIG. 21A and FIG. 21B, numerals 501A, 501B denote memory cell arrays having memory cells not being erasure targets, and numerals 502A, 502B denote memory cell arrays having memory cells being erasure targets. Numerals 503A, 503B, 503C denote word line drivers and plate line drivers, and numerals 504A, 504B, 504C denote column decoders. Arranging wells, where the memory cells being erasure targets are formed, together as illustrated in FIG. 21B makes it possible to reduce the well separation region and reduce the circuit area.

A disclosed semiconductor memory device applies a fixed potential to another electrode of a capacitor and applies a potential being a forward voltage with respect to a junction between first conductive type source and drain and a second conductive type well to the second conductive type well to thereby apply a certain voltage to the capacitor, thereby making it possible to erase data in a memory cell and collectively erase data in a short time only by adding a simple peripheral circuit thereto with a unit cell having the same structure and area as those in the prior art.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor memory device, comprising:
a memory cell array including a memory cell, the memory cell including a capacitor and an access transistor, the access transistor being a first conductive type transistor formed in a second conductive type well and including a source and a drain one of which is connected to one electrode of the capacitor and another of which is connected to a bit line; and
a control circuit which applies a first potential to another electrode of the capacitor and applies a second potential to the second conductive type well when erasing data in the memory cell, and applies a third potential to the second conductive type well in a normal operation, the first potential being a fixed potential, the second potential being a forward voltage with respect to a junction between the first conductive type source and drain and the second conductive type well, the third potential not being the forward voltage with respect to the junction between the first conductive type source and drain and the second conductive type well.

2. The semiconductor memory device according to claim 1,
wherein the memory cell is a non-volatile memory cell.

3. The semiconductor memory device according to claim 2,
wherein the capacitor of the memory cell is a ferroelectric capacitor.

4. The semiconductor memory device according to claim 1,
wherein the access transistor is an N-type transistor,
wherein the control circuit applies the same potential to the second conductive type well where the access transistor is formed and to a first conductive type well where the second conductive type well is formed, and
wherein the third potential is lower than the second potential.

5. The semiconductor memory device according to claim 1,
wherein the access transistor is a P-type transistor,
wherein the control circuit applies the second potential to the second conductive type well where the access transistor is formed when erasing data in the memory cell, and
wherein the third potential is higher than the second potential.

6. The semiconductor memory device according to claim 1,
wherein the memory cell array includes a plurality of the memory cells,
wherein the plurality of memory cells include:
a first memory cell including an access transistor formed in the second conductive type well of which potential is controlled by the control circuit; and
a second memory cell including an access transistor formed in the second conductive type well to which a potential not being the forward voltage regardless of control by the control circuit is applied.

7. The semiconductor memory device according to claim 6,
wherein the first memory cell and a peripheral circuit which drives the first memory cell are arranged together.

8. The semiconductor memory device according to claim 1,
wherein after the data in the memory cell is erased, “0” data is outputted as read data from the memory cell.

9. The semiconductor memory device according to claim 1, further comprising:
a sense amplifier that senses data read from the memory cell,
wherein when the sense amplifier senses the data read from the memory cell, offset is applied thereto.

10. The semiconductor memory device according to claim 9, further comprising:
a level shift circuit which generates the offset in a reference potential used for determination of the data read from the memory cell.

11. The semiconductor memory device according to claim 9,
wherein the offset is generated by connecting a second capacitor, different from the capacitor, to the bit line.

12. The semiconductor memory device according to claim 9,
wherein the memory cell array includes a plurality of the memory cells,
wherein the plurality of memory cells include a third memory cell used for generation of a reference potential used for determination of the data read from the plurality of memory cells, and a fourth memory cell other than the third memory cell, and
wherein the offset is generated by making a capacitance value of a capacitor of the third memory cell different from a capacitance value of a capacitor of the fourth memory cell.

13. The semiconductor memory device according to claim 1, further comprising:
a logic circuit which detects that the memory cell is in an erase state after the data in the memory cell is erased, and masks data to be outputted.

14. The semiconductor memory device according to claim 1,
wherein the memory cell array includes a plurality of the memory cells,
wherein when erasing data from the memory cell array, data in a memory cell used for generation of a reference potential used for determination of data read from the memory cell, among memory cells included in the memory cell array, is erased.

15. The semiconductor memory device according to claim 1,
wherein the memory cell array includes a plurality of the memory cells,
wherein when erasing data from the memory cell array, data in a memory cell having a flag, among memory cells included in the memory cell array, is erased.

16. A control method of a semiconductor memory device including a memory cell array including a memory cell, the memory cell including a capacitor and an access transistor, the access transistor being a first conductive type transistor formed in a second conductive type well and including a source and a drain one of which is connected to one electrode of the capacitor and another of which is connected to a bit line, the control method comprising:
applying a first potential to another electrode of the capacitor and applying a second potential to the second conductive type well when erasing data in the memory cell, the first potential being a fixed potential, the second potential being a forward voltage with respect to a junction between the first conductive type source and drain and the second conductive type well; and
applying a third potential to the second conductive type well in a normal operation, the third potential not being the forward voltage with respect to the junction between the first conductive type source and drain and the second conductive type well.
